(19) United States
(12) Patent Application Publication
(10) Pub. No.: US 2011/0108703 A1
(43) Pub. Date: May 12, 2011

(54) SEGMENTED GUARD STRIP

(75) Inventor: Mannie DORFAN, Nes Ziona (IL)

(73) Assignee: ORBOTECH MEDICAL SOLUTIONS LTD., Rehovot (IL)

(21) Appl. No.: 12/615,814

(22) Filed: Nov. 10, 2009

(51) Int. Cl. H01L 27/14; H01L 31/02

(52) U.S. Cl. 250/208.1; 438/98; 257/E31.11

(57) ABSTRACT

A semiconductor detector array including a substrate formed of a semiconductor material and defining a detector array surface including first and second opposite facing surfaces and at least one side wall, electrodes operative as anodes and cathodes of the detector array, formed on the respective first and second opposite facing surfaces, electrical insulation formed along at least part of the at least one side wall and at least one segmented electrical conductor formed over at least part of the electrical insulation along the at least part of the at least one side wall.

### BACKGROUND OF THE INVENTION

The following patents are believed to represent the current state of the art: U.S. Pat. Nos. 5,905,264; 6,034,373.

### FIELD OF THE INVENTION

The present invention relates generally to radiation detectors and more particularly to radiation detectors having a guard strip to improve the performance of their side wall pixels.

### SUMMARY OF THE INVENTION

The present invention seeks to provide a semiconductor detector array with improved performance due to confinement of the effects of false signal-generating events to individual side wall pixels at which the events occur and due to reduced sensitivity of the side wall pixels to such false signal-generating events.

There is thus provided in accordance with a preferred embodiment of the present invention a semiconductor detector array including a substrate formed of a semiconductor material and defining a detector array surface including first and second opposite facing surfaces and at least one side wall, electrodes operative as anodes and cathodes of the detector array, formed on the respective first and second opposite facing surfaces, electrical insulation formed along at least part of the at least one side wall and at least one segmented electrical conductor formed over at least part of the electrical insulation along the at least part of the at least one side wall.

Preferably, the at least one segmented electrical conductor includes electrically conductive segments separated by gaps.

Preferably, the electrically conductive segments are aligned with the anodes and the gaps are aligned with corners of the semiconductor detector array.

Alternatively, the gaps are aligned with corners of the semiconductor detector array.

Preferably, the electrical insulation includes an insulative material selected from a group including polymers, epoxies, photoresists, plastic tapes, sticky tapes, labels and sticky labels.

Preferably, the segmented electrical conductor includes a conductive material selected from a group including metals, metal films, conductive epoxies, conductive photoresists, conductive organic tapes, tapes, sticky conductive tapes, labels and sticky labels.

Preferably, the electrical insulation is formed using a technique selected from a group of techniques including bonding, coating, deposition, painting, spraying, injecting or printing.

Preferably, the segmented electrical conductor is formed using a technique selected from a group of techniques including bonding, coating, deposition, evaporating, spraying, painting, injecting or printing.

In accordance with a preferred embodiment of the present invention, the semiconductor detector array also includes an electrical insulator formed over the at least one segmented electrical conductor, thereby to provide electrical insulation along at least part of the at least one side wall between the at least one electrical conductor and the anodes and cathodes which lie adjacent the at least one side wall.

Preferably, the at least one segmented electrical conductor includes electrically conductive segments separated by gaps.

Preferably, the electrically conductive segments are aligned with the anodes and the gaps are aligned with corners of the semiconductor detector array.

Alternatively, the gaps are aligned with corners of the semiconductor detector array.

Preferably, the electrical insulation and the electrical insulator include an insulative material selected from a group including polymers, epoxies, photoresists, plastic tapes, sticky tapes, labels and sticky labels.

Preferably, the segmented electrical conductor includes a conductive material selected from a group including metals, metal films, conductive epoxies, conductive photoresists, conductive organic tapes, tapes, sticky conductive tapes, labels and sticky labels.

Preferably, the electrical insulation and the electrical insulator are formed using a technique selected from a group of techniques including bonding, coating, deposition, painting, spraying, injecting or printing.

Preferably, the segmented electrical conductor is formed using a technique selected from a group of techniques including bonding, coating, deposition, evaporating, spraying, painting, injecting or printing.

There is also provided in accordance with another preferred embodiment of the present invention a method for improving the performance of a semiconductor detector array, the semiconductor detector array including a substrate formed of a semiconductor material and defining a detector array surface including first and second opposite facing surfaces and at least one side wall, and also including electrodes operative as anodes and cathodes of the detector array, formed on the respective first and second opposite facing surfaces, the method including the steps of forming electrical insulation along at least part of the at least one side wall and forming at least one segmented electrical conductor over at least part of the electrical insulation along the at least part of the at least one side wall.

Preferably, the forming of the at least one segmented electrical conductor includes forming electrically conductive segments separated by gaps.

Preferably, the method includes the step of aligning the electrically conductive segments with the anodes and aligning the gaps with corners of the semiconductor detector array.

Alternatively, the method includes the step of aligning the gaps with corners of the semiconductor detector array.

Preferably, the forming of the electrical insulation includes forming an insulative material selected from a group including polymers, epoxies, photoresists, plastic tapes, sticky tapes, labels and sticky labels.

Preferably, the forming of the segmented electrical conductor includes forming a conductive material selected from a group including metals, metal films, conductive epoxies, conductive photoresists, conductive organic tapes, tapes, sticky conductive tapes, labels and sticky labels.

Preferably, the forming of the electrical insulation is carried out using a technique selected from a group of techniques including bonding, coating, deposition, painting, spraying, injecting or printing.

Preferably, the forming of the segmented electrical conductor is carried out using a technique selected from a group of techniques including bonding, coating, deposition, evaporating, spraying, painting, injecting or printing.

In accordance with a further preferred embodiment of the present invention, the method also includes the step of forming an electrical insulator over the at least one segmented electrical conductor, thereby to provide electrical insulation along at least part of the at least one side wall between the at least one electrical conductor and the anodes and cathodes which lie adjacent the at least one side wall.

Preferably, the forming of the at least one segmented electrical conductor includes forming electrically conductive segments separated by gaps.

Preferably, the method includes the step of aligning the electrically conductive segments with the anodes and aligning the gaps with corners of the semiconductor detector array.

Alternatively, the method includes the step of aligning the gaps with corners of the semiconductor detector array.

Preferably, the forming of the electrical insulation and the electrical insulator includes forming an insulative material selected from a group including polymers, epoxies, photoresists, plastic tapes, sticky tapes, labels and sticky labels.

Preferably, the forming of the segmented electrical conductor includes forming a conductive material selected from a group including metals, metal films, conductive epoxies, conductive photoresists, conductive organic tapes, tapes, sticky conductive tapes, labels and sticky labels.

Preferably, the forming of the electrical insulation and the electrical insulator is carried out using a technique selected from a group of techniques including bonding, coating, deposition, painting, spraying, injecting or printing.

Preferably, the forming of the segmented electrical conductor is carried out using a technique selected from a group of techniques including bonding, coating, deposition, evaporating, spraying, painting, injecting or printing.

### BRIEF DESCRIPTION OF THE DRAWINGS

The present invention will be understood and appreciated more fully from the following detailed description, taken in conjunction with the drawings in which:

FIGS. 1A and 1B are simplified respective top and side view illustrations of a semiconductor detector array with a guard strip, constructed and operative in accordance with a first preferred embodiment of the present invention, in which the guard strip includes a segmented electrical conductor, the segments of which are aligned with the pixellated detector anodes and corners of the detector array;

FIGS. 2A and 2B are simplified respective top and side view illustrations of a semiconductor detector array with a guard strip, constructed and operative in accordance with a second preferred embodiment of the present invention, in which the guard strip includes a segmented electrical conductor, the segments of which are aligned with the corners of the detector array;

FIGS. 3A and 3B are simplified respective top and side view illustrations of a semiconductor detector array similar to that of FIGS. 1A and 1B but including electrical insulation disposed over the segmented electrical conductor;

FIGS. 4A and 4B are simplified respective top and side view illustrations of a semiconductor detector array similar to that of FIGS. 2A and 2B but including electrical insulation disposed over the segmented electrical conductor;

FIG. 5 is a side view illustration of two abutting semiconductor detector arrays of FIGS. 1A and 1B;

FIG. 6 is a side view illustration of two abutting semiconductor detector arrays of FIGS. 2A and 2B;

FIG. 7 is a side view illustration of two abutting semiconductor detectors arrays of FIGS. 3A and 3B; and

FIG. 8 is a side view illustration of two abutting semiconductor detector arrays of FIGS. 4A and 4B.

### DETAILED DESCRIPTION OF A PREFERRED EMBODIMENT

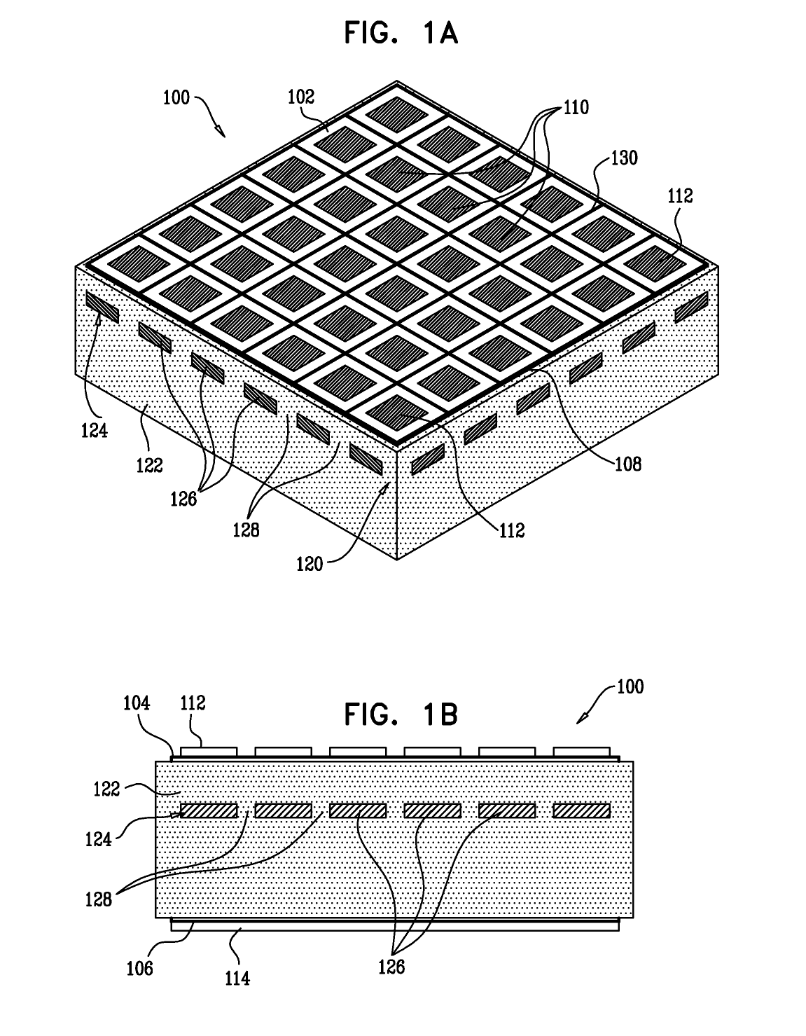

Reference is now made to FIGS. 1A and 1B, which are simplified respective top and side view illustrations of a semiconductor detector array having a guard strip, constructed and operative in accordance with a first preferred embodiment of the present invention, in which the guard strip includes a segmented electrical conductor, the segments of which are aligned with the pixellated detector anodes and corners of the detector array.

As seen in FIGS. 1A and 1B, there is provided a semiconductor detector array 100. Semiconductor detector array 100 includes a semiconductor substrate 102, preferably formed of CdZnTe (CZT) or any other suitable semiconductor material. Semiconductor substrate 102 defines a detector array surface having first and second opposite facing surfaces, designated by reference numerals 104 and 106 respectively, and side walls 108. Pixellated anodes 110, including side wall pixellated anodes 112, are formed on the first opposite facing surface 104 and a monolithic cathode 114 is formed on the second opposite facing surface 106.

A guard strip 120, constructed and operative in accordance with a first preferred embodiment of the present invention, is formed along at least part of at least one of side walls 108. Guard strip 120 includes electrical insulation 122 over at least part of which is formed a segmented electrical conductor 124. Segmented electrical conductor 124 includes electrically conductive segments 126 separated by gaps 128.

Electrical insulation 122 may be formed from a variety of insulative materials such as polymers, epoxies, photoresists, plastic tapes, sticky tapes, labels and sticky labels. Electrical insulation 122 may be applied using a range of techniques including bonding, coating, deposition, painting, spraying, injecting or printing.

Segmented electrical conductor 124 may be formed from a variety of conductive materials such as metals, metal films, conductive epoxies, conductive photoresists, conductive organic tapes and sticky conductive tapes and labels. Segmented electrical conductor 124 may be applied using a range of techniques, including bonding, coating, deposition, evaporation, spraying, painting, injecting or printing.

Grid lines 130 on the surface of semiconductor 102 indicate shadowed regions produced by a collimator (not shown) that partially blocks radiation impinging on detector array 100. The collimator is generally attached to detector array 100 on the side of cathode 114. As seen clearly in FIG. 1A, electrically conductive segments 126 of segmented electrical conductor 124 are aligned with pixellated anodes 110 and gaps 128 of segmented electrical conductor 124 are aligned with grid lines 130. Since no or very few photons arrive at the detector in the region of grid lines 130, no or very few events occur in semiconductor 102 in this region and there is therefore no degradation in performance of segmented electrical conductor 124 as a result of gaps 128, since gaps 128 correspond to regions in which no or very few events occur.

It has been experimentally found that the electrical influence of conductive segments 126 extends over regions greater than the dimensions of the footprints of these segments. Provided that the gaps 128 between conductive segments 126 are sufficiently small, the efficiency of segmented electrical conductor 124 is comparable to the efficiency of a continuous electrical conductor along the length of the detector perimeter. It has been found that the efficiency of segmented electrical conductor 124 remains comparable to the efficiency of a continuous electrical conductor for gaps 128 up to the order of magnitude of about 1 mm.

Electrical insulation 122 and gaps 128 serve to electrically isolate conductive segments 126 from each other. The electrical isolation of the conductive segments 126 results in a number of key improvements in the performance of guard strip 120 in comparison to the performance of a continuous guard strip, to be detailed herein below.

A first advantage arising from the mutual electrical isolation of conductive segments 126 is the prevention of spreading of self-triggering between side wall pixellated anodes 112. Self-triggering and consequent generation of false events may occur in side wall pixellated anodes 112 due to locally damaged regions of guard strip 120. As a result of the electrical isolation of conductive segments 126, the effect of such damage on side wall pixellated anodes 112 remains localized rather than spreading along the entire edge or even perimeter of the detector unit.

In addition to the electrical isolation of conductive segments 126 preventing spreading of self-triggering between side wall pixellated anodes 112 of a single detector unit, the electrical isolation of the conductive segments also prevents spreading of self-triggering between side wall pixellated anodes of abutting detector units. Such spread would otherwise occur due to possible direct electrical contact between the conductive segments of the guard strips of adjacent modules or due to capacitive coupling between electrical conductors of abutting detector units.

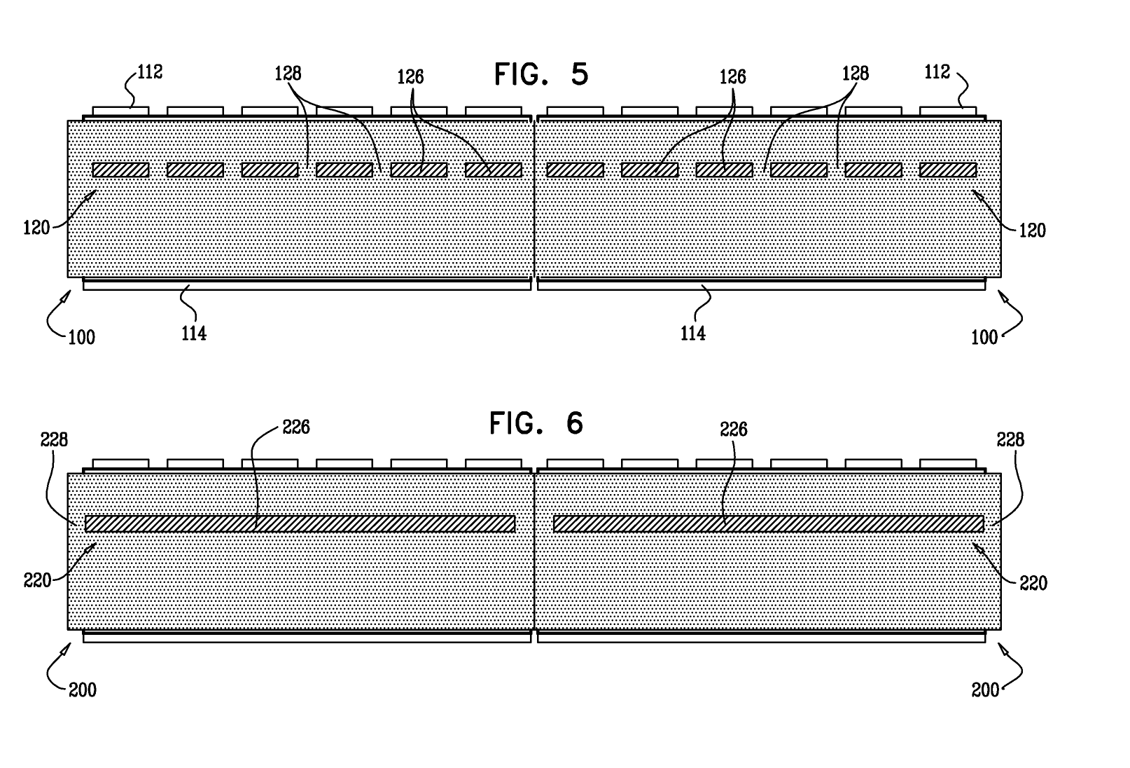

FIG. 5 is a side view illustration of two abutting semiconductor detector arrays of FIGS. 1A and 1B. Self-triggering and consequent generation of false events that may occur in side wall pixellated anodes as a result of local damage is prevented from spreading from one detector unit to the other, due to electrical isolation of each of their conductive segments.

The confinement of a false event to a single localized pixel rather than it influencing a group of pixels is highly significant, since whereas the reconstruction algorithms used by imaging systems that employ pixellated solid-state detectors, such as detector 100, are able to tolerate a certain level of isolated non-functioning pixels, the algorithms are not able to tolerate the malfunction of a group of adjacent pixels. When a group of adjacent pixels malfunctions these algorithms cannot compensate for the resultant effects on the image and artifacts become apparent in the reconstructed images. The prevention of this by the localization of the false events is thus highly desirable.

A further advantage created by the mutual electrical isolation of conductive segments 126 may be better understood by considering the operation of detector array 100. In operation of detector array 100, electrons from a detector leakage current are directed towards electrical insulation 122 by mirror charges that build up on electrical conductor 124. The charge build up on electrical insulation 122 reaches equilibrium when the accumulated charge on electrical insulation 122 is sufficient to reject the arrival of additional electrons. The accumulated charge on electrical insulation 122 repels electrons arising from measured signals from side walls 108, thereby allowing better charge collection of the signal charge. The performance of side wall pixellated anodes 112 is thus improved.

At equilibrium, electrical conductor 124 is charged to a certain voltage, which is self-tuned. In the absence of gaps 128 between conductive segments 126, the voltage of the electrical conductor 124 would be required to be the same for all locations along side walls 108, resulting in a self-tuned voltage that is not necessary optimal for all points along electrical conductor 124.

Electrical isolation of conductive segments 126 allows the self-tuned voltage to which each conductive segment is charged to reach its optimum for each side wall pixel individually, independent of the other side wall pixels. Achieving optimal self-tuned voltages, which may differ from conductive segment to conductive segment, results in the optimal performance of each side wall pixel.

Yet a further advantage arising from the present arrangement of conductive segments 126 is that conductive segments 126 are aligned with the corners of detector array 100 such that the corner regions do not include conductive segments 126. The corners of detector array 100 are the most likely location at which damage to guard strip 120 occurs, due to the sharp bending of the guard strip around these corners. Such damage may lead to self-triggering and the generation of false events, as described herein above. By distancing the conductive segments 126 from the corners of the detector array 100, the likelihood of damage to guard strip 120 is minimized.

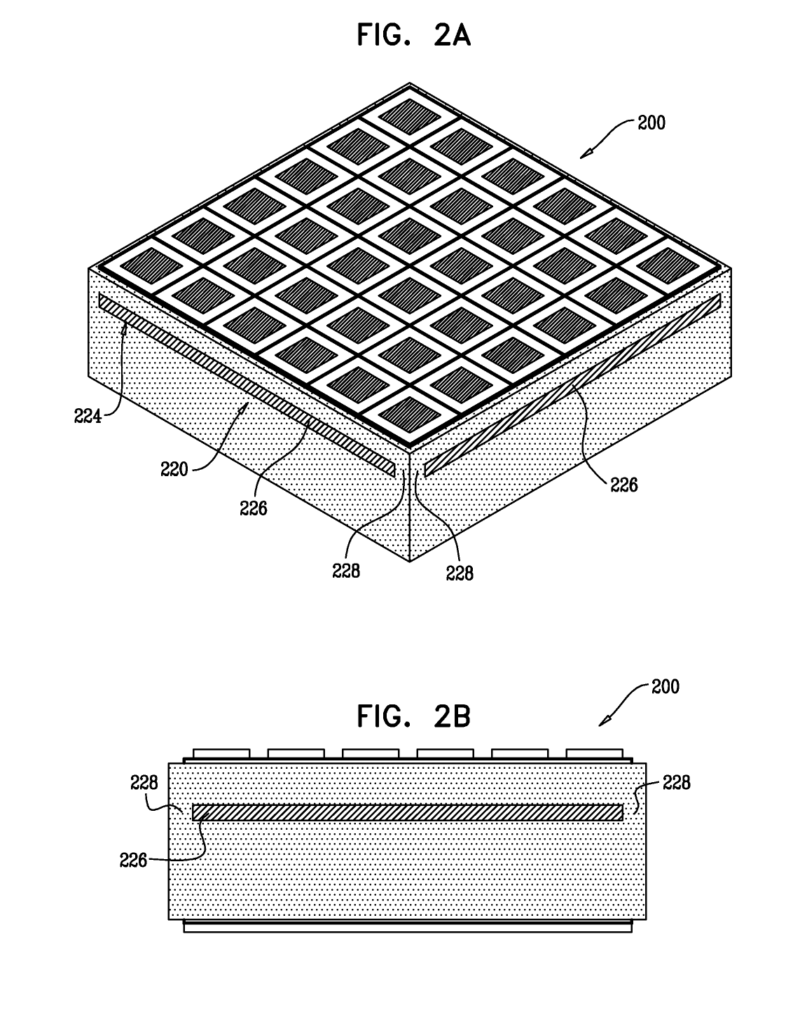

Reference is now made to FIGS. 2A and 2B which are simplified respective top and side view illustrations of a semiconductor detector array having a guard strip, constructed and operative in accordance with a second preferred embodiment of the present invention, in which the guard strip includes a segmented electrical conductor, the segments of which are aligned with the corners of the detector array.

As seen in FIGS. 2A and 2B there is provided a semiconductor detector array 200 with a guard strip 220. Guard strip 220 includes segmented electrical conductor 224 having conductive segments 226 separated by gaps 228. Semiconductor detector array 200 resembles semiconductor detector array 100 of FIGS. 1A and 1B in every respect, with the exception of the structure of segmented electrical conductor 224. In contrast to segmented electrical conductor 124 of FIGS. 1A and 1B, in which the segments are aligned with the pixellated anodes and the corners of the detector array, in segmented electrical conductor 224 the conductive segments 226 are only aligned with the corners of the detector array.

This embodiment shares the advantages of the embodiment described in reference to FIGS. 1A and 1B, including localization of false signal-generating events via prevention spreading of false events between side wall pixels within and between abutting detector units, optimal individual self-tuned segment voltages and reduced likelihood of damage to guard strip 220.

FIG. 6 is a side view illustration of two abutting semiconductor detector arrays of FIGS. 2A and 2B. The problem of self-triggering and the generation of false events in side wall pixels that may be caused by locally damaged regions, as described hereinabove, is prevented from spreading from one detector unit to the other due to the electrical isolation of each of their conductive segments.

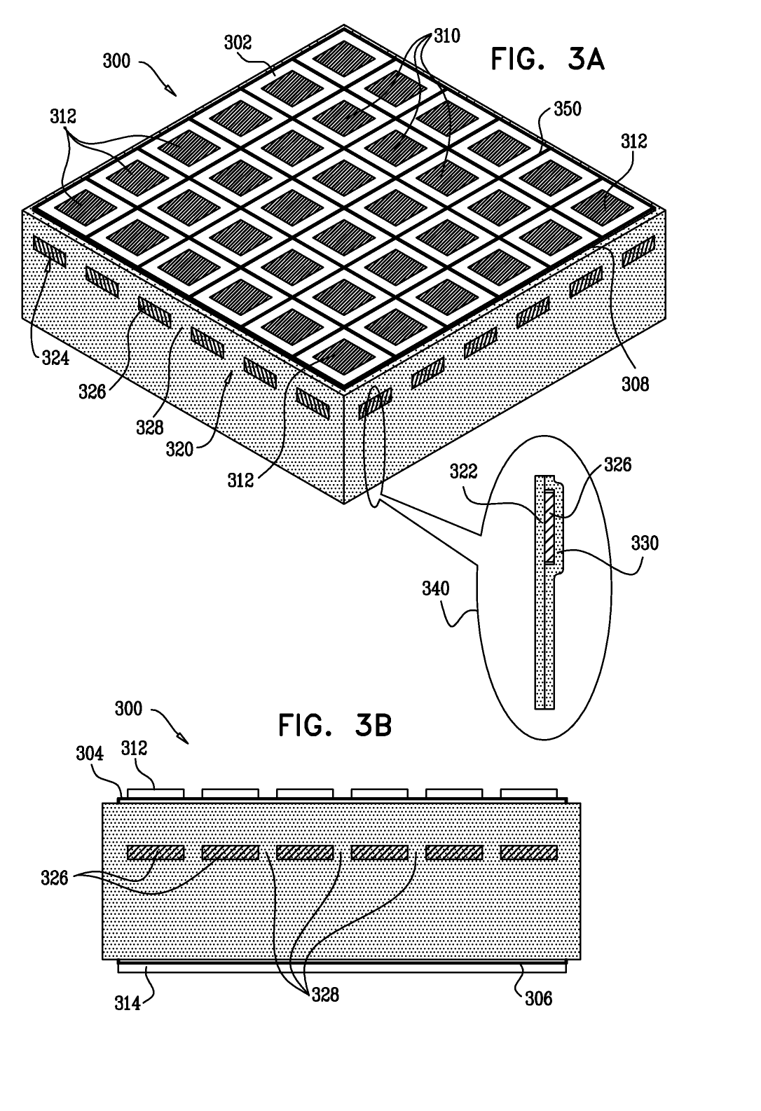

Reference is now made to FIGS. 3A and 3B which are simplified respective top and side view illustrations of a semiconductor detector array similar to that of FIGS. 1A and 1B but including electrical insulation disposed over the segmented electrical conductor;

As seen in FIGS. 3A and 3B there is provided a semiconductor detector array 300. Semiconductor detector array 300 includes a semiconductor substrate 302, preferably formed of CdZnTe (CZT) or any other suitable semiconductor material. Semiconductor substrate 302 defines a detector array surface having first and second opposite facing surfaces, designated by reference numerals 304 and 306 respectively, and side walls 308. Pixellated anodes 310, including side wall pixellated anodes 312, are formed on the first opposite facing surface 304 and a monolithic cathode 314 is formed on the second opposite facing surface 306.

A guard strip 320, constructed and operative in accordance with a further preferred embodiment of the present invention, is formed along at least part of at least one of side walls 308. Guard strip 320 includes electrical insulation 322 over at least part of which is formed a segmented electrical conductor 324. Segmented electrical conductor 324 includes electrically conductive segments 326 separated by gaps 328. A second external layer of electrical insulation 330 is formed over at least part of segmented electrical conductor 324, such that electrical conductor 324 is sandwiched between two layers of electrical insulation as seen at enlargement 340 in FIG. 3A.

In the absence of electrical insulation 330, electrical conductor 324 would be exposed to the ambient, as are electrical conductors 124 and 224 of FIGS. 1A and 2A respectively. Changes in temperature or humidity may lead to the formation of trails or films of condensed vapor on the sides of the detector array. These trails or films may form unstable electrical conduction paths, resulting in sudden alterations in potential of the electrical conductor and causing self-triggering and generation of false events in side wall pixellated anodes of the detector array.

The second external layer of electrical insulation 330, in combination with electrical insulation 322, overcomes this problem by encapsulating segmented electrical conductor 324. Electrical insulation 330 prevents electrical contact between electrical conductor 324 and the detector anodes or cathode, thereby preventing the formation of unstable electrical conduction paths. Guard strip 320 is therefore less sensitive to changes in humidity and side wall pixellated anodes 312 are correspondingly less sensitive to self-triggering and the generation of false events.

Electrical insulation 322 and 330 may be formed from a variety of insulative materials such as polymers, epoxies, photoresists, plastic tapes, sticky tapes, labels and sticky labels. Electrical insulation 322 and 330 may be applied using a range of techniques including bonding, coating, deposition, painting, spraying, injecting or printing.

Segmented electrical conductor 324 may be formed from a variety of conductive materials such as metals, metal films, conductive epoxies, conductive photoresists, conductive organic tapes and sticky conductive tapes and labels. Segmented electrical conductor 124 may be applied using a range of techniques, including bonding, coating, deposition, evaporation, spraying, painting, injecting or printing.

Grid lines 350 on the surface of semiconductor 302 indicate shadowed regions produced by a collimator (not shown) that partially blocks radiation impinging on detector array 300. The collimator is generally attached to detector array 300 on the side of cathode 314. As seen clearly in FIG. 3A, electrically conductive segments 326 of segmented electrical conductor 324 are aligned with pixellated anodes 310 and gaps 328 of segmented electrical conductor 324 are aligned with grid lines 350.

This embodiment of the present invention shares the advantages of the embodiment described in reference to FIGS. 1A and 1B, detailed above, with the additional advantage of reduced sensitivity of side wall pixellated anodes 312 to ambient changes, due to the presence of additional external electrical insulation 330.

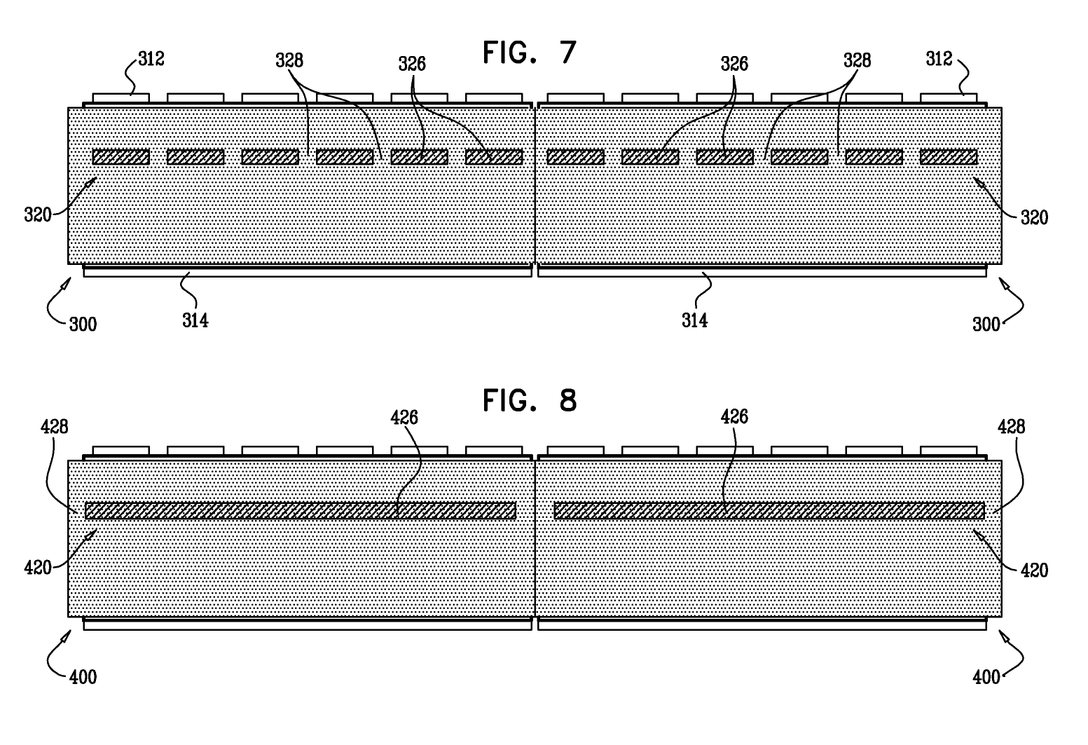

FIG. 7 is a side view illustration of two abutting semiconductor detector arrays of FIGS. 3A and 3B. The problem of self-triggering and the generation of false events in side wall pixels that may be caused by locally damaged regions, as described hereinabove, is prevented from spreading from one detector unit to the other due to electrical isolation and encapsulation of each of their conductive segments.

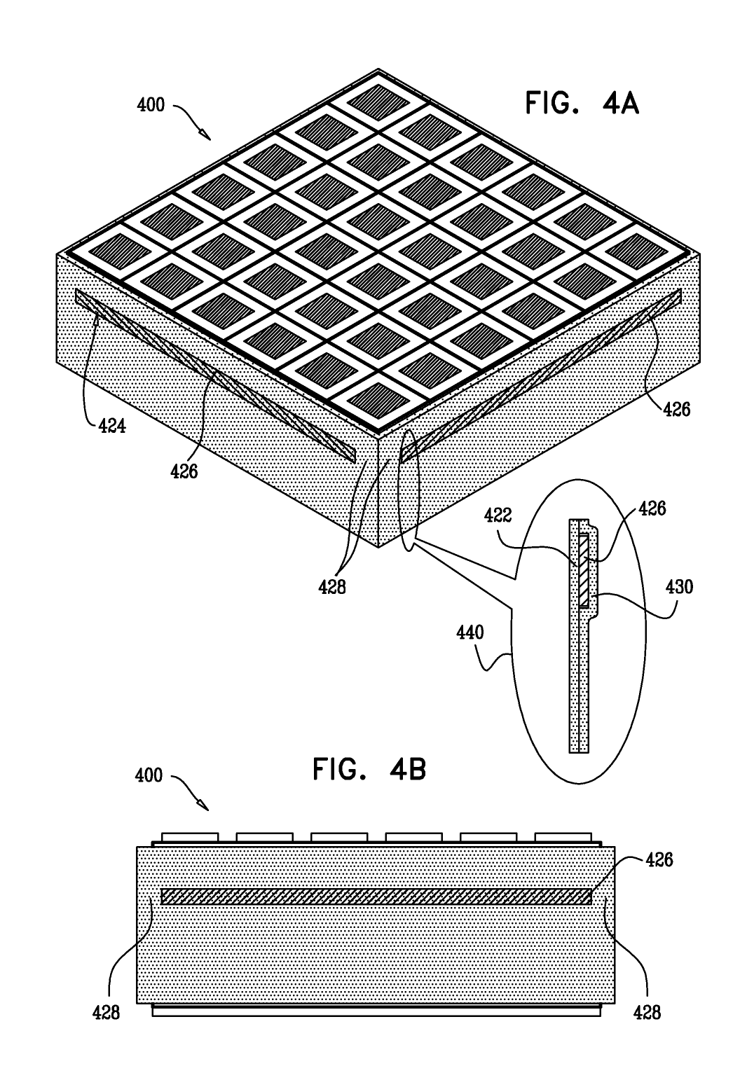

Reference is now made to FIGS. 4A and 4B which are simplified respective top and side view illustrations of a semiconductor detector array similar to that of FIGS. 2A and 2B but including electrical insulation disposed over the segmented electrical conductor.

As seen in FIGS. 4A and 4B there is provided a semiconductor detector array 400 with a guard strip 420. Guard strip 420 includes electrical insulation 422 and segmented electrical conductor 424 having conductive segments 426 separated by gaps 428. The conductive segments 426 and gaps 428 are aligned with the corners of the detector array as in the detector array of FIG. 2A.

A second external layer of electrical insulation 430 is formed over at least part of segmented electrical conductor 424, such that electrical conductor 424 is sandwiched between two layers of electrical insulation as seen at enlargement 440 in FIG. 4A.

The second external layer of electrical insulation 430, in combination with electrical insulation 422, encapsulates segmented electrical conductor 424, thereby preventing electrical contact between electrical conductor 424 and the detector anodes or cathode and improving the performance of guard strip 420 as described hereinabove.

This embodiment of the present invention shares the advantages of the embodiment described in reference to FIGS. 2A and 2B, with the additional advantage of reduced sensitivity of detector 400 to ambient changes due to the presence of additional external electrical insulation 430.

FIG. 8 is a side view illustration of two abutting semiconductor detector arrays of FIGS. 4A and 4B. The problem of self-triggering and the generation of false events in side wall pixels that may occur as a result of locally damaged regions, as described hereinabove, is prevented from spreading from one detector unit to the other due to electrical isolation and encapsulation of each of their conductive segments.

It will be appreciated by persons skilled in the art that the present invention is not limited by what has been particularly claimed hereinbelow. Rather the scope of the present invention includes various combinations and subcombinations of the features described hereinabove as well as modifications and variations thereof as would occur to persons skilled in the art upon reading the foregoing description with reference to the drawings and which are not in the prior art. In particular, it will be appreciated that the rectangular shape of the conductive segments shown in FIGS. 1A-8 is shown by way of example only and that the conductive segments may be embodied in a variety of different shapes.

1. A semiconductor detector array comprising:
a substrate formed of a semiconductor material and defining a detector array surface comprising first and second opposite facing surfaces and at least one side wall;
electrodes operative as anodes and cathodes of said detector array, formed on respective said first and second opposite facing surfaces;
electrical insulation formed along at least part of said at least one side wall; and
at least one segmented electrical conductor formed over at least part of said electrical insulation along said at least part of said at least one side wall.

2. A semiconductor detector array according to claim 1 and also comprising an electrical insulator formed over said at least one segmented electrical conductor, thereby to provide electrical insulation along at least part of said at least one side wall between said at least one electrical conductor and said anodes and cathodes which lie adjacent said at least one side wall.

3. A semiconductor detector array according to claim 1 and wherein said at least one segmented electrical conductor comprises electrically conductive segments separated by gaps.

4. A semiconductor detector array according to claim 3 and wherein said electrically conductive segments are aligned with said anodes.

5. A semiconductor detector array according to claim 4 and wherein said gaps are aligned with corners of said semiconductor detector array.

6. A semiconductor detector array according to claim 3 and wherein said gaps are aligned with corners of said semiconductor detector array.

7. A semiconductor detector array according to claim 2 and wherein said at least one segmented electrical conductor comprises electrically conductive segments separated by gaps.

8. A semiconductor detector array according to claim 7 and wherein said electrically conductive segments are aligned with said anodes.

9. A semiconductor detector array according to claim 8 and wherein said gaps are aligned with corners of said semiconductor detector array.

10. A semiconductor detector array according to claim 7 and wherein said gaps are aligned with corners of said semiconductor detector array.

11. A semiconductor detector array according to claim 1 and wherein said electrical insulation comprises an insulative material selected from a group including polymers, epoxies, photoresists, plastic tapes, sticky tapes, labels and sticky labels.

12. A semiconductor detector array according to claim 2 and wherein said electrical insulation and said electrical insulator comprise an insulative material selected from a group including polymers, epoxies, photoresists, plastic tapes, sticky tapes, labels and sticky labels.

13. A semiconductor detector array according to claim 1 and wherein said segmented electrical conductor comprises a conductive material selected from a group including metals, metal films, conductive epoxies, conductive photoresists, conductive organic tapes, tapes, sticky conductive tapes, labels and sticky labels.

14. A semiconductor detector array according to claim 2 and wherein said segmented electrical conductor comprises a conductive material selected from a group including metals, metal films, conductive epoxies, conductive photoresists, conductive organic tapes, tapes, sticky conductive tapes, labels and sticky labels.

15. A semiconductor detector array according to claim 1 and wherein said electrical insulation is formed using a technique selected from a group of techniques including bonding, coating, deposition, painting, spraying, injecting or printing.

16. A semiconductor detector array according to claim 2 and wherein said electrical insulation and said electrical insulator are formed using a technique selected from a group of techniques including bonding, coating, deposition, painting, spraying, injecting or printing.

17. A semiconductor detector array according to claim 1 and wherein said segmented electrical conductor is formed using a technique selected from a group of techniques including bonding, coating, deposition, evaporating, spraying, painting, injecting or printing.

18. A semiconductor detector array according to claim 2 and wherein said segmented electrical conductor is formed using a technique selected from a group of techniques including bonding, coating, deposition, evaporating, spraying, painting, injecting or printing.

19. A method for improving the performance of a semiconductor detector array, said semiconductor detector array comprising a substrate formed of a semiconductor material and defining a detector array surface comprising first and second opposite facing surfaces and at least one side wall, and also comprising electrodes operative as anodes and cathodes of said detector array, formed on respective said first and second opposite facing surfaces, the method comprising the steps of:
forming electrical insulation along at least part of said at least one side wall; and forming at least one segmented electrical conductor over at least part of said electrical insulation along said at least part of said at least one side wall.

20. A method according to claim 19 and also comprising the step of forming an electrical insulator over said at least one segmented electrical conductor, thereby to provide electrical insulation along at least part of said at least one side wall between said at least one electrical conductor and said anodes and cathodes which lie adjacent said at least one side wall.

21. A method according to claim 19 and wherein said forming said at least one segmented electrical conductor comprises forming electrically conductive segments separated by gaps.

22. A method according to claim 21 and comprising the step of aligning said electrically conductive segments with said anodes.

23. A method according to claim 22 and comprising the step of aligning said gaps with corners of said semiconductor detector array.

24. A method according to claim 21 and comprising the step of aligning said gaps with corners of said semiconductor detector array.

25. A method according to claim 20 and wherein said forming said at least one segmented electrical conductor comprises forming electrically conductive segments separated by gaps.

26. A method according to claim 25 and comprising the step of aligning said electrically conductive segments with said anodes.

27. A method according to claim 26 and comprising the step of aligning said gaps with corners of said semiconductor detector array.

28. A method according to claim 25 and comprising the step of aligning said gaps with corners of said semiconductor detector array.

29. A method according to claim 19 and wherein said forming said electrical insulation comprises forming an insulative material selected from a group including polymers, epoxies, photoresists, plastic tapes, sticky tapes, labels and sticky labels.

30. A method according to claim 20 and wherein said forming said electrical insulation and said electrical insulator comprises forming an insulative material selected from a group including polymers, epoxies, photoresists, plastic tapes, sticky tapes, labels and sticky labels.

31. A method according to claim 19 and wherein said forming said segmented electrical conductor comprises forming a conductive material selected from a group including metals, metal films, conductive epoxies, conductive photoresists, conductive organic tapes, tapes, sticky conductive tapes, labels and sticky labels.

32. A method according to claim 20 and wherein said forming said segmented electrical conductor comprises forming a conductive material selected from a group including metals, metal films, conductive epoxies, conductive photoresists, conductive organic tapes, tapes, sticky conductive tapes, labels and sticky labels.

33. A method according to claim 19 and wherein said forming said electrical insulation is carried out using a technique selected from a group of techniques including bonding, coating, deposition, painting, spraying, injecting or printing.

34. A method according to claim 20 and wherein said forming said electrical insulation and said electrical insulator is carried out using a technique selected from a group of techniques including bonding, coating, deposition, painting, spraying, injecting or printing.

35. A method according to claim 19 and wherein said forming said segmented electrical conductor is carried out using a technique selected from a group of techniques including bonding, coating, deposition, evaporating, spraying, painting, injecting or printing.

36. A method according to claim 20 and wherein said forming said segmented electrical conductor is carried out using a technique selected from a group of techniques including bonding, coating, deposition, evaporating, spraying, painting, injecting or printing.
